(19) United States
(12) Patent Application Publication
(10) Pub. No.: US 2025/0105121 A1
(43) Pub. Date: Mar. 27, 2025

(54) SEMICONDUCTOR DEVICE, CIRCUIT BOARD, AND SEMICONDUCTOR DEVICE MANUFACTURING METHOD

(71) Applicant: Kioxia Corporation, Tokyo (JP)

(72) Inventor: Mihoko MORIYAMA, Yokosuka Kanagawa (JP)

(21) Appl. No.: 18/882,324

(22) Filed: Sep. 11, 2024

(30) Foreign Application Priority Data
Sep. 21, 2023 (JP) 2023-155486

(51) Int. Cl. H01L 23/498; H01L 21/48; H01L 25/16

(52) U.S. Cl. CPC H01L 23/49827; H01L 21/486; H01L 25/165; H10D 1/68

(57) ABSTRACT

A semiconductor device, a circuit board, and a semiconductor device manufacturing method, capable of preventing an unexpected short circuit between wires connected to the circuit board are provided. The semiconductor device comprises: a circuit board including a first surface and a second surface on an opposite side of the circuit board as the first surface; a semiconductor chip provided on the first surface of the circuit board; a passive component connected to an electrode that is provided on the first surface of the circuit board via solder; and sealing resin covering the first surface of the circuit board and surfaces of the semiconductor chip and the passive component. A trench is formed through the first surface of the circuit board along at least a part of a peripheral edge of the electrode, and a plated layer is formed on an inner wall of the trench.

### CROSS-REFERENCE TO RELATED APPLICATIONS

This application is based upon and claims the benefit of priority from Japanese Patent Application No. 2023-155486, filed Sep. 21, 2023, the entire contents of which are incorporated herein by reference.

### FIELD

Embodiments described herein relate generally to a semiconductor device, a circuit board, and a semiconductor device manufacturing method.

### BACKGROUND

A semiconductor device in which a passive component such as a capacitor is provided on a circuit board together with a semiconductor chip has been proposed.

### BRIEF DESCRIPTION OF THE DRAWINGS

FIG. 1 is a sectional view illustrating an example of a semiconductor device of an

embodiment.

FIG. 2 is a diagram illustrating an example of disposition of a memory chip and a capacitor mounted on a circuit board.

FIG. 3 is a sectional view illustrating an example of a circuit board of the embodiment.

FIG. 4A is a diagram illustrating a manufacturing process of the circuit board illustrated in FIG. 3.

FIG. 4B is a diagram illustrating a manufacturing process of the circuit board illustrated in FIG. 3.

FIG. 4C is a diagram illustrating a manufacturing process of the circuit board illustrated in FIG. 3.

FIG. 4D is a diagram illustrating a manufacturing process of the circuit board illustrated in FIG. 3.

FIG. 4E is a diagram illustrating a manufacturing process of the circuit board illustrated in FIG. 3.

FIG. 4F is a diagram illustrating a manufacturing process of the circuit board illustrated in FIG. 3.

FIG. 4G is a diagram illustrating a manufacturing process of the circuit board illustrated in FIG. 3.

FIG. 4H is a diagram illustrating a manufacturing process of the circuit board illustrated in FIG. 3.

FIG. 4I is a diagram illustrating a manufacturing process of the circuit board illustrated in FIG. 3.

FIG. 5 is a sectional view illustrating another example of the circuit board of the embodiment.

FIG. 6 is a flowchart illustrating an example of a manufacturing process of a semiconductor device of the embodiment.

FIG. 7A is a plan view in which a rectangular area B surrounded by a dotted line in FIG. 2 is enlarged.

FIG. 7B is a sectional view along a C-C′ line of the circuit board illustrated in FIG. 7A.

FIG. 7C is a sectional view along a D-D′ line of the circuit board illustrated in FIG. 7A.

FIG. 7D is a sectional view along the C-C′ line of the circuit board illustrated in FIG. 7A, and illustrates a cross section after reflow treatment.

FIG. 8 is another sectional view along the C-C′ line of the circuit board illustrated in FIG. 7A.

### DETAILED DESCRIPTION

Embodiments provide a semiconductor device, a circuit board, and a semiconductor device manufacturing method, capable of preventing an unexpected short circuit between wires connected to the circuit board.

In general, according to one embodiment, a semiconductor device of the present embodiment includes: a circuit board including a first surface and a second surface on an opposite side of the circuit board as the first surface; a semiconductor chip provided on the first surface of the circuit board; a passive component connected to an electrode, wherein the electrode is provided on the first surface of the circuit board via solder; and sealing resin covering the first surface of the circuit board and surfaces of the semiconductor chip and the passive component. A trench is formed through the first surface of the circuit board along at least a part of a peripheral edge of the electrode, and a plated layer is formed on an inner wall of the trench.

Hereinafter, the embodiment will be described with reference to the drawings.

In description below, an XYZ coordinate system which is an example of an orthogonal coordinate system is used. That is, a plane parallel to a surface of a circuit board 2 of a semiconductor device 1 is an XY plane, and a direction orthogonal to the XY plane is a Z axis. In addition, an X axis and a Y axis are two orthogonal directions within the XY plane. Note that an up-down direction described herein with respect to a wiring board, the Z axis being normal to the wiring board, does not indicate an up-down relation according to a vertical direction.

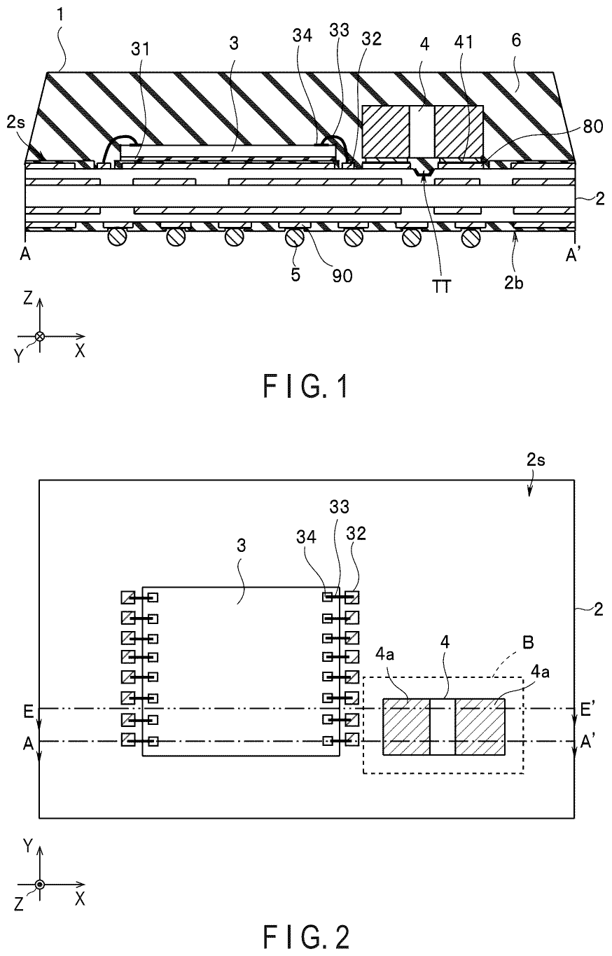

FIG. 1 is a sectional view illustrating an example of the semiconductor device 1 of the embodiment. A ratio between components in FIG. 1 is different from an actual ratio in practice. The semiconductor device 1 of the embodiment is, for example, a semiconductor package formed by sealing a semiconductor chip and a passive component or the like loaded on a wiring board with mold resin. The semiconductor device 1 includes the circuit board 2, a NAND type flash memory chip (indicated as a memory chip, hereinafter) 3 as a semiconductor chip, a capacitor 4 as a passive component, solder balls 5, and mold resin 6. The mold resin 6 covers a first surface 2s of the circuit board 2 and surfaces of the memory chip 3 and the capacitor 4. The mold resin 6 is an example of sealing resin. Note that the semiconductor device 1 may include passive components other than the capacitor 4, such as a resistance element and a coil. Further, the semiconductor device 1 may include a semiconductor chip other than the memory chip 3, such as a controller chip.

The circuit board 2 is, for example, an insulating resin circuit board or a ceramics circuit board or the like provided with a wiring layer on a surface or on the inside. The circuit board 2 includes a first surface 2s and a second surface 2b. On the first surface 2s, the memory chip 3 and the capacitor 4 are provided. The memory chip 3 is physically bonded to the first surface 2s via a film-like adhesive agent 31. The film-like adhesive agent 31 is a non-conductive tape-like adhesive agent including a resin adhesive component containing thermosetting resin (for example, epoxy-based resin, polyimide-based resin, acrylic-based resin, or mixed resin thereof). The film-like adhesive agent 31 closely attaches objects stuck on and under the film-like adhesive agent 31 when heat and a load are applied. The memory chip 3 is electrically connected to the wiring layer via pads 32 provided on the circuit board 2, using conductive wires 33 or the like. The capacitor 4 is physically and electrically connected to pads (electrodes) 80 provided on the first surface 2s of the circuit board 2 via solder 41. For the solder 41, lead-free solder is used. For example, the solder 41 has a composition (Sn—Ag—Cu) in which Sn (tin) is a main component and Ag (silver) and Cu (copper) are added. In addition, in a case of the composition in which Sn is the main component, the solder 41 may have a composition (Sn—Bi) in which Bi (bismuth) is added, a composition (Sn-Zn) in which Zn (zinc) is added, or a composition (Sn—Ag) in which Ag is added. On the second surface 2b, the solder balls 5 as external terminals for a ball grid array (BGA) package are provided. The solder ball 5 is an example of an external device connecting terminal. The solder balls 5 are physically and electrically connected to lands 90 provided on the second surface 2b of the circuit board 2.

FIG. 2 is a diagram illustrating an example of disposition of a memory chip 3 and a capacitor 4 loaded on a circuit board 2. FIG. 2 is a top view viewing the circuit board 2 on which the memory chip 3 and the capacitor 4 are disposed from an upper part (in the Z direction) of a first surface 2s. Note that FIG. 1 illustrates a cross section in the case of cutting the semiconductor device 1 at a position indicated by an A-A′ line in FIG. 2.

As illustrated in FIG. 2, on the circuit board 2, the memory chip 3 and the capacitor 4 are provided. The memory chip 3 is a thin plate whose flat surface has a rectangular shape. The memory chip 3 is disposed on the first surface 2s of the circuit board 2 such that a thickness direction of the thin plate is parallel to a Z direction.

The capacitor 4 has a rectangular parallelepiped shape. The capacitor 4 is disposed such that a bottom surface faces the first surface 2s of the circuit board 2. The capacitor 4 is disposed at a predetermined distance from the memory chip 3 so as not to overlap with the memory chip 3 in the Z direction. On the capacitor 4, a pair of external electrodes 4a are provided on a pair of surfaces (on a pair of end faces) that are orthogonal to the bottom surface and face each other in a long side direction of the bottom surface.

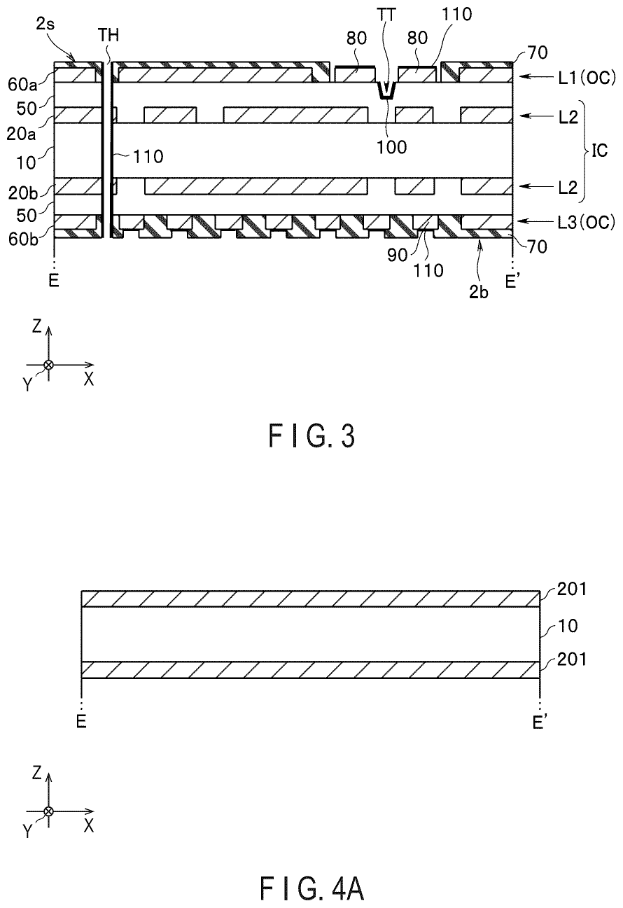

Next, a structure of the circuit board 2 will be described using FIG. 3. FIG. 3 is a sectional view illustrating an example of the circuit board 2 of the embodiment. Note that FIG. 3 illustrates the sectional view in the case of cutting the circuit board 2 on which the memory chip 3 and the capacitor 4 are disposed as illustrated in FIG. 2 along an E-E′ line. The circuit board 2 includes an internal circuit IC and an external circuit OC.

The external circuit OC includes wiring layers L1 and L3 provided on the first surface 2s and the second surface 2b, respectively. In the wiring layer L1 provided on the first surface 2s, the pads 32 to be electrically connected to terminals 34 of the memory chip 3 and the pads 80 to be electrically connected to the capacitor 4 are provided. Further, in the wiring layer L1, wires 60a are provided. The wires 60a include the one that electrically connects the pads 32 to the terminals 34 of the memory chip 3 and the pads 80 with the capacitor 4. A surface of the wiring layer L1 is covered with a solder resist 70. The solder resist 70 is provided with an opening so as to expose a surface of the pads 80. Under the wiring layer L1, the internal circuit IC includes a prepreg layer 50. In the prepreg layer 50, a trench TT is formed. The trench TT is formed so as to capture solder grains that scatter unintentionally when adding the solder 41 to an upper surface of the pads 80. Therefore, the trench TT is formed near (along at least a part of) a peripheral edge of the pads 80, where the solder grains tend to scatter. FIG. 3 illustrates a structure in which the trench TT is formed between the two pads 80, as an example. On an inner wall of the trench TT, a plated layer 100 is formed. Using the plated layer 100, it is possible to prevent the solder grains captured inside the trench TT from permeating through the prepreg layer 50 and reaching a wiring layer L2.

The internal circuit IC includes multiple wiring layers formed by laminating the plurality of wiring layers L2. FIG. 3 illustrates the internal circuit IC formed by laminating the two wiring layers L2, as an example. The pad 80 and the wire 60a included in the wiring layer L1 and a wire 20a included in the wiring layer L2 are electrically connected via an unillustrated via hole. Between wires 20a and 20b laminated and included in the wiring layer L2 (between the wires that are adjacent to each other from up to down), a core layer 10 is formed. The core layer 10 is, for example, a hard planar member formed of glass fibers and epoxy resin. The wires 20a and 20b on an upper surface and a lower surface of the core layer 10, respectively, are electrically connected via an unillustrated through-hole wire. While FIG. 3 illustrates the circuit board 2 including the core layer 10, a so-called coreless circuit board not including the core layer 10 may be also used. In this case, the plurality of wires 20a and 20b included in the wiring layer L2 are laminated holding the prepreg layer 50 therebetween.

In the wiring layer L3 provided on the second surface 2b, the plurality of lands 90 for electrically connecting the solder balls 5 as external terminals and wires 60b are provided. A surface of the wiring layer L3 is covered with the solder resist 70. The solder resist 70 is provided with openings so as to expose surfaces of all the lands 90. The wire 20b included in the wiring layer L2 and the lands 90 are electrically connected via an unillustrated via hole. By such a configuration, the memory chip 3 is electrically connected to the solder balls 5 via respective parts of the circuit board 2. In addition, on the circuit board 2, a through-hole TH passing through from a surface of the solder resist 70 covering the wiring layer L1 to a surface of the solder resist 70 covering the wiring layer L3 is also formed.

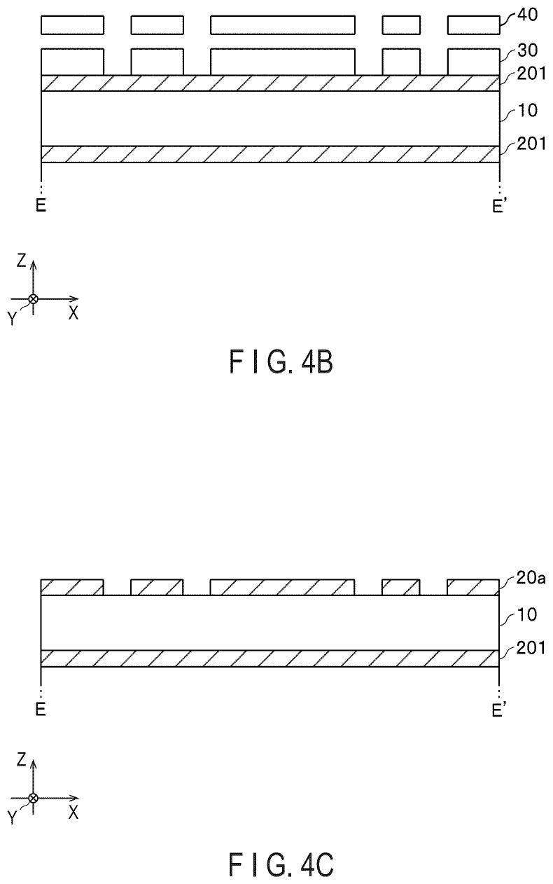

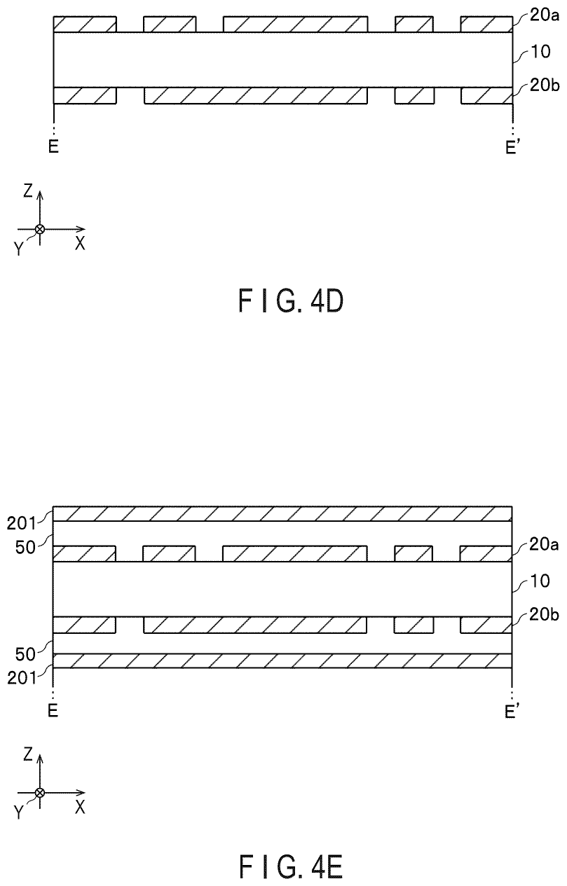

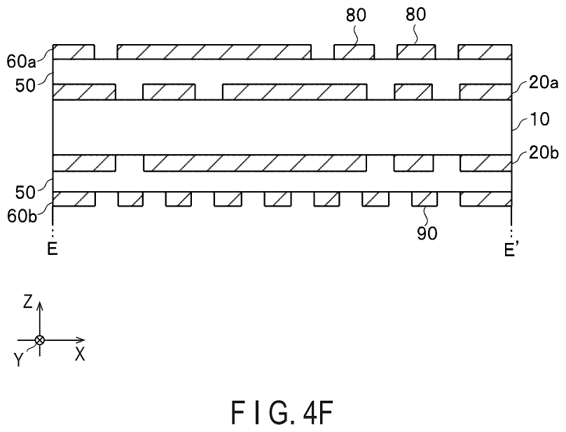

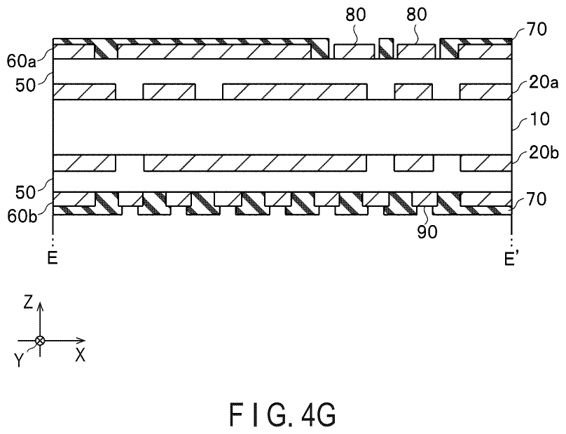

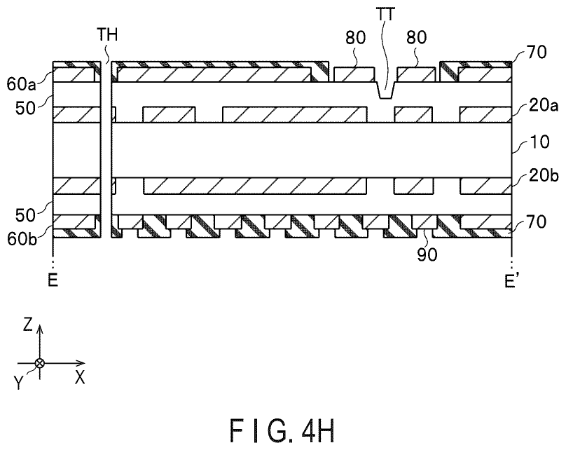

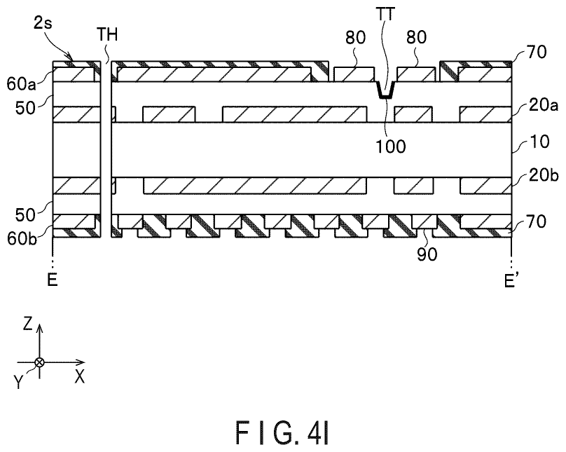

FIG. 4A to FIG. 4I are diagrams illustrating a manufacturing process of a circuit board. First, as illustrated in FIG. 4A, copper foil 201 is stuck to an upper surface and a lower surface of the core layer 10, and is heated/pressurized. A circuit board for which the copper foil is stuck to the upper and lower surfaces of the core layer in this way is also referred to as a copper clad laminate (CCL). The copper clad laminate is widely used for an internal circuit.

Subsequently, as illustrated in FIG. 4B, photoresist 30 is applied to a surface of the copper foil 201 stuck to the upper surface of the core layer 10. At an upper part of the photoresist 30, a template 40 is disposed for which a wiring pattern of the internal circuit IC is provided. Ultraviolet (UV) light is emitted using an unillustrated UV light source (such as a high pressure mercury lamp) from the upper part of the template 40, and the wiring pattern of the internal circuit IC from the template 40 is transferred to the photoresist 30 using a photolithography technique.

Next, as illustrated in FIG. 4C, the copper foil 201 is etched using an anisotropic etching technique or the like with the patterned photoresist 30 as a mask. When etching is ended, the photoresist 30 is removed using a washing technique or the like, and formation of the wire 20a is completed. As illustrated in FIG. 4D, the copper foil 201 on the lower surface of the core layer 10 is also processed using the photolithography technique and the anisotropic etching technique, and the wire 20b is formed.

Subsequently, as illustrated in FIG. 4E, the copper foil 201 is bonded to the surfaces of the wires 20a and 20b via the prepreg layers 50. A prepreg of the prepreg layer 50 is a resin sheet in a semi-cured state, containing resin in glass fibers. The upper and lower parts of the copper clad laminate are held by the prepreg layers 50, and the copper foil 201 is layered on the surface of each prepreg layer 50. In this state, when the laminated body is heated/pressurized from the upper and lower parts, the prepreg is cured, and the copper clad laminate and the copper foil 201 are bonded.

Next, as illustrated in FIG. 4F, the copper foil 201 bonded to the upper surface of the upper prepreg layer 50 is processed using the photolithography technique and the anisotropic etching technique, and the wire 60a and the pads 80 are formed. In addition, the copper foil 201 bonded to the lower surface of the lower prepreg layer 50 is processed using the photolithography technique and the anisotropic etching technique or the like, and the wire 60b and the lands 90 are formed.

Then, as illustrated in FIG. 4G, on the surfaces of the wiring layers L1 and L3 that form the external circuit OC, the solder resist 70 as a protective film is added. For example, a sheet-like solder resist is stuck, and only a part to be cured is irradiated with the ultraviolet light and exposed using the photolithography technique or the like. Then, an uncured part is removed using the anisotropic etching technique or the like. That is, the solder resist 70 is processed such that the solder resist covering the surfaces of the pads 80 and the lands 90 is removed and the openings are formed.

Next, as illustrated in FIG. 4H, the through-hole TH passing through from the surface of one solder resist 70 to the surface of the other solder resist 70 is formed. The through-hole TH is formed using a drill for micromachining. When forming the through-hole TH of the circuit board 2, the trench TT is also formed. The trench TT is formed using a drill for micromachining at a position away from the pad 80 by a predetermined distance. The trench TT is formed to such a depth that it does not pass through the prepreg layer 50 and does not reach the wiring layer L2, the depth of the trench TT thus being less than a distance between the first surface 2s and the internal circuit IC. A position and a shape for forming the trench TT will be described later in detail.

Subsequently, as illustrated in FIG. 41, the inner wall of the trench TT is plated and the plated layer 100 is formed. For plating, a material (for example, Ni (nickel)) having low wettability to solder (e.g., low wettability to Sn) is used. Since Ni cannot be directly plated to the prepreg layer 50, Ni plating is executed with palladium as a catalyst. Specifically, first, the upper surface of the first surface 2s is covered with an unillustrated mask having an opening in an area where a trench TT is formed, and a thin palladium solution is applied to the inner wall of the trench TT using a sputtering technique or the like. The inside of the trench TT may be immersed in the thin palladium solution. Then, the inner wall of the trench TT is plated with Ni using an electroless plating method. Note that the material that forms the plated layer 100 needs to have the low wettability to the solder, and the material other than Ni, such as Cr (chromium), for example, may be used. A thickness of the plated layer 100 formed in this way is about 3 μm for example. After Ni plating, the unillustrated mask is removed, the inside of the trench TT is washed, and the palladium solution is completely removed. If the palladium solution remains inside the trench TT, there is a possibility that Cu (copper) is deposited on the surface of the plated layer 100 formed by Ni, and the wettability to the solder increases. In order to prevent it, washing is performed after plating.

Finally, plating is performed on the inner wall of the through-hole TH with a material such as Cu (copper) to form the plated layer 110 illustrated in FIG. 3, and manufacturing of the circuit board 2 is ended.

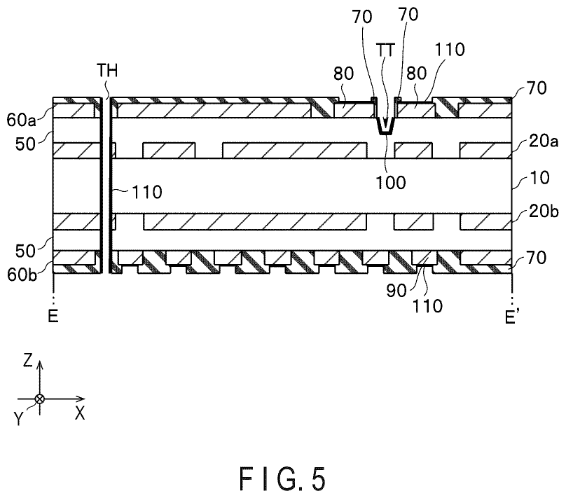

FIG. 5 is a sectional view illustrating another example of the circuit board 2 of the embodiment. In the method described above, when forming the opening on the solder resist 70 on the side of the first surface 2s so as to expose the surface of the pad 80, the solder resist 70 is processed such that a size of the opening becomes larger than a size of the pad 80 (see FIG. 3 and FIG. 4G). In contrast, as illustrated in FIG. 5, the solder resist 70 may be processed such that the opening is formed to be smaller than the size of the pad 80 and a part of the solder resist 70 covers the upper surface of the pad 80. In the case of a structure illustrated in FIG. 5 as well, the trench TT is formed to such a depth that it does not pass through the prepreg layer 50 and does not reach the wiring layer L2.

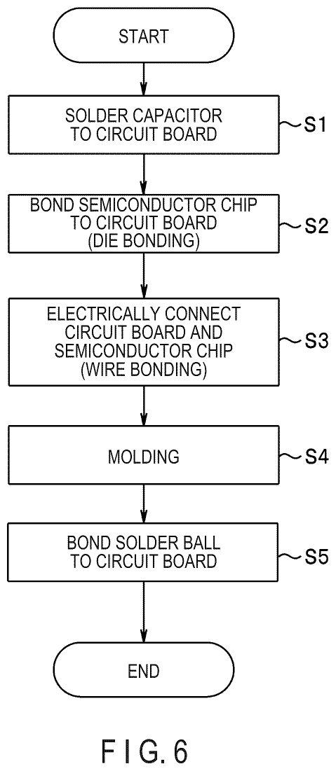

Next, a manufacturing method of the semiconductor device 1 will be described. FIG. 6 is a flowchart illustrating an example of a manufacturing process of the semiconductor device 1 of the embodiment. First, the capacitor 4 is soldered to the pads 80 provided on the circuit board 2 (S1). In S1, first, solder paste is applied onto the first surface 2s of the circuit board 2 using a method of squeegee printing for example, and the solder 41 is applied to the pads 80. When release of the squeegee printing is not good for example, solder grains may scatter from the solder paste and get stuck to unintended places other than the pads 80.

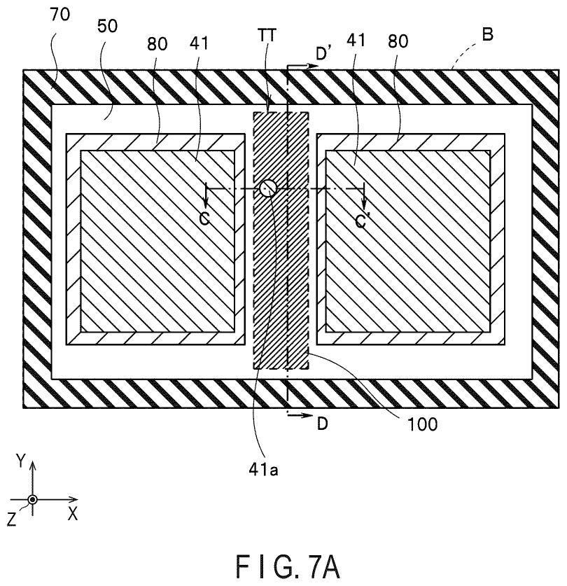

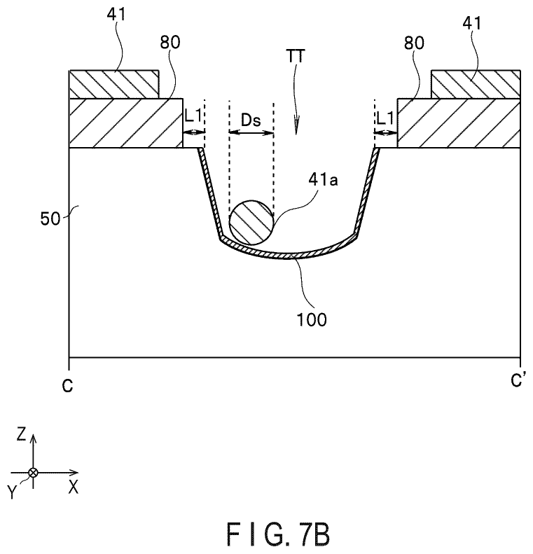

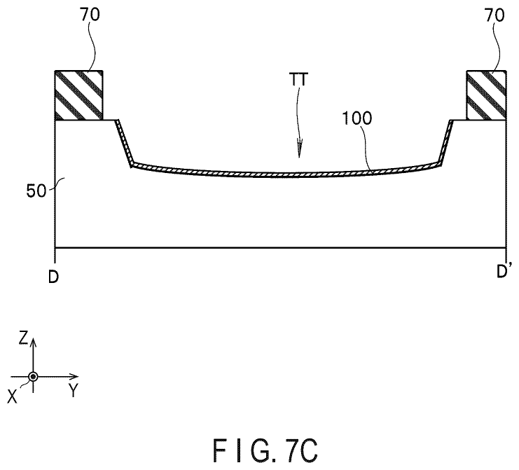

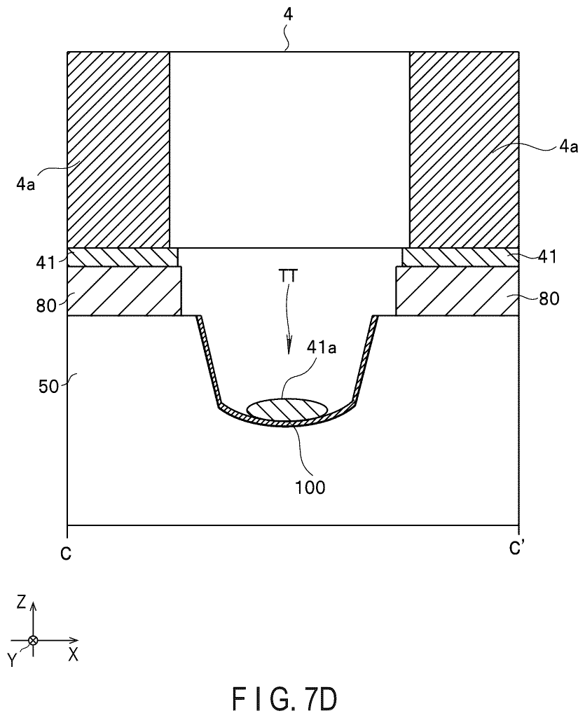

FIG. 7A is a plan view in which a rectangular area B surrounded by the dotted line in FIG. 2, is enlarged. As illustrated in FIG. 7A and as mentioned earlier, the trench TT is formed near (along at least a part of) a peripheral edge of the pads 80. FIG. 7A illustrates the plan view in a state before loading the capacitor 4, that is, at the point of time when the solder 41 is applied to the pads 80. A solder grain 41a is captured inside the trench TT formed between the two pads 80. Here, the shape of the trench TT will be described in detail. The trench TT is formed in a gap of the two pads 80. An upper surface of the trench TT has a rectangular shape. In a direction (Y direction in FIG. 7A) in which opposing sides of the two pads 80 extend, a length of the trench TT is formed to be longer than a length of the pads 80.

FIG. 7B is a sectional view along a C-C′ line of the circuit board illustrated in FIG. 7A. In addition, FIG. 7C is a sectional view along a D-D′ line of the circuit board illustrated in FIG. 7A. Note that FIG. 7B and FIG. 7C illustrate the structure above the wiring layer L2. As illustrated in FIG. 7B, the trench TT is formed between the two opposing sides of the two pads 80 in an X direction. Two sides of the trench TT extending in the Y direction are formed at positions away from the two opposing sides of the two pads 80 by a distance L1, respectively. When a diameter of the scattering solder grain 41a is a length Ds, the distance L1 is preferably a half of the length Ds or shorter. That is because, by making a distance between the trench TT and the pad 80 be a radius of the solder grain 41a or shorter, even when the solder grain 41a scatters in the prepreg layer 50 provided between the pad 80 and the trench TT in the X direction, it easily rolls down to the inside of the trench TT and a likelihood that the trench TT captures the solder grain 41a increases.

As illustrated in FIG. 7B and FIG. 7C, a width of the trench TT is not uniform in a depth direction (Z direction) and is formed so as to be increasingly narrow as the depth of the trench TT increases. Further, a bottom part of the trench TT may be a planar shape but is preferably a curved shape that is convex downwards. By attaining such a shape, the solder grain 41a that has rolled down to the inside of the trench TT is captured at the center of a bottom part of the trench TT and the likelihood of getting out of the trench TT is reduced. By forming the trench TT in this way, it is possible to prevent the solder grain 41a from scattering on the upper surface of the solder resist 70 and the upper surface of the prepreg layer 50, and it is possible to prevent an unintended short circuit in the wiring layer L1.

FIG. 7D is a sectional view along the C-C′ line of the circuit board illustrated in FIG. 7A, and illustrates a cross section after reflow treatment. Specifically, when formation of the solder 41 on the pad 80 is ended, each of the pair of electrodes 4a provided on the capacitor 4 and each of the solder 41 applied to the pair of pads 80, are positioned. Reflow is subsequently performed to fix the solder 41 and the capacitor 4. In the reflow, by heating, melting, and then cooling the solder 41, the capacitor 4 is fixed to the pad 80 with the solder 41 as an adhesive agent. By heating the solder 41 in the reflow treatment, the solder grain 41a that has scattered and has been captured inside the trench TT is also melted. The melted solder grain 41a has a possibility of permeating through the prepreg layer 50 and reaching the wiring layer L2.

However, on the inner wall of the trench TT, the plated layer 100 having the low wettability to the solder grain 41a such as Ni is formed. Therefore, even when the solder grain 41a is melted as illustrated in FIG. 7D, it is possible to prevent the solder grain 41a from permeating through the prepreg layer 50 by the plated layer 100. Thus, it is possible to prevent an unexpected short circuit between the wiring layers L1 and L2 due to the solder grain 41a that has scattered. When the lead-free solder having Sn as the main component is used as the solder 41 as described above, the wettability of Ni and the solder 41 is lowered by Sn. Therefore, it is possible to prevent the solder grain 41a from permeating through the prepreg layer 50 by the plated layer 100 regardless of the component added to Sn.

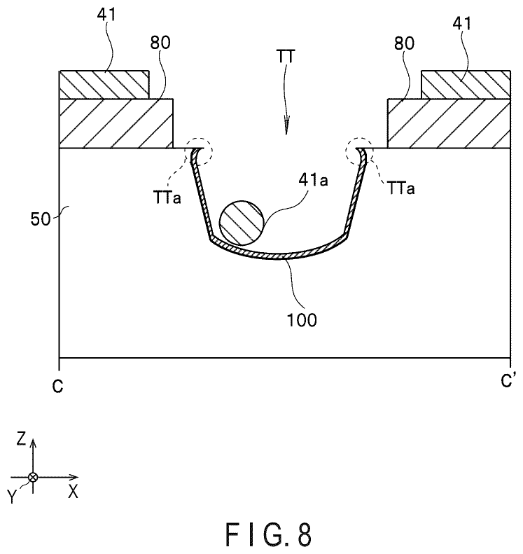

Note that the shape of the trench TT may be a shape illustrated in FIG. 8 in order to prevent the solder grain 41a captured in the trench TT from scattering again to the outside of the trench TT. FIG. 8 is another sectional view along the C-C′ line of the circuit board illustrated in FIG. 7A. The trench TT is formed such that the width of the trench TT is widened as the depth increases from an entrance of the trench TT to a predetermined depth, and is formed such that the width of the trench TT becomes increasingly narrow as the depth increases similarly to FIG. 7B after the predetermined depth. That is, a so-called return structure TTa is provided on the entrance of the trench TT. By providing the return structure TTa, it is possible to further suppress the solder grain 41a captured in the trench TT from scattering again, and it is possible to further prevent an unintended short circuit.

Returning to the flow in FIG. 6, after the capacitor 4 and the pads 80 are physically and electrically connected in S1, the memory chip 3 (a semiconductor chip) is bonded on the first surface 2s of the circuit board 2 (S2). S2 is a process called die bonding. A predetermined area of the first surface 2s of the circuit board 2 and a back surface of the memory chip 3 are bonded using the film-like adhesive agent 31 such as a die attach film (DAF), for example. Subsequently, the circuit board 2 is heated by an oven and the film-like adhesive agent 31 is cured. Further, the terminals 34 of the memory chip 3 (semiconductor chip) and the pads 32 included in the wiring layer L1 of the circuit board 2 are connected using the metal wires 33 of gold (Au) or the like (S3). S3 is a process called wire bonding.

Next, the circuit board 2 is sealed with resin (S4). S4 is a process called molding. In S4, since the inside of the trench TT is also filled with the mold resin 6, the captured solder grain 41a is fixed inside the trench TT. Subsequently, the solder balls 5 that are the external terminals are bonded to the lands 90 included in the wiring layer L3 of the circuit board 2 using a conductive adhesive agent such as solder paste. Then, the circuit board 2 is heated by the reflow treatment and the lands 90 and the solder balls 5 are fixed (S5). By executing the above processes, the semiconductor device 1 of the embodiment is manufactured.

In this way, according to the present embodiment, the trench TT is formed along the pads 80 provided on the first surface 2s of the circuit board 2. By such a structure, even when a part of the solder 41 becomes granular and scatters to a place other than the pad at the time of adding the solder 41 to the upper surface of the pads 80, it can be captured inside the trench TT. Thus, it is possible to prevent an unexpected short circuit in the wiring layer L1. Further, on the inner wall of the trench TT, the plated layer 100 using the metal having the low wettability to the solder 41 is formed. Thus, even when heat treatment of reflow or the like is executed and the solder 41 is melted, it is possible to prevent it from permeating to the wiring layer L2 below the trench TT, and it is also possible to prevent an unexpected short circuit in the wiring layer L2 and between the wiring layers L1 and L2.

Note that the wiring layers laminated on the circuit board 2 are not limited to four layers. The circuit board 2 may be formed of only the external circuit OC, that is, only the two wiring layers L1 and L3, or may be formed of a multilayered wiring layer of five or more layers. In addition, while the trench TT is formed in the gap between the pair of pads 80 above, the trench TT may be formed so as to correspond to each side of the pad 80. For example, the trench TT may be formed so as to surround a periphery of the pad 80. Further, in the case of connecting an electronic component such as the memory chip 3 to a pad using solder using a “flip chip method” (not illustrated), the trench TT may be formed in a pad that electrically connects the electronic component to the circuit board 2.

While certain embodiments have been described, these embodiments have been presented by way of example only, and are not intended to limit the scope of the invention. Indeed, the novel devices and methods described herein may be embodied in a variety of other forms; furthermore, various omissions, substitutions and changes in the form of the embodiments described herein may be made without departing from the spirit of the invention. The accompanying claims and their equivalents are intended to cover such forms or modification as would fall within the scope and spirit of the invention.

What is claimed is:

1. A semiconductor device comprising:
a circuit board including a first surface and a second surface on an opposite side of the circuit board as the first surface;
a semiconductor chip provided on the first surface of the circuit board;
a passive component connected to a first electrode via solder, wherein the first electrode is provided on the first surface of the circuit board; and
sealing resin covering the first surface of the circuit board and surfaces of the semiconductor chip and the passive component, wherein
a trench is formed through the first surface of the circuit board along at least a part of a peripheral edge of the first electrode, and
a plated layer is formed on an inner wall of the trench.

2. The semiconductor device of claim 1, wherein
a second electrode is provided on the first surface of the circuit board, and
the trench is formed between the first and second electrodes.

3. The semiconductor device of claim 2, wherein
the passive component is a capacitor including a third electrode and a fourth electrode, the third and fourth electrodes being external electrodes, and
the first and second electrodes are connected to the third and fourth electrodes, respectively.

4. The semiconductor device of claim 1, wherein
the plated layer is formed of a metal material having low wettability to the solder.

5. The semiconductor device of claim 4, wherein the metal material is nickel.

6. The semiconductor device of claim 1, wherein
the trench is formed such that a width of the trench becomes increasingly narrow as a depth of the trench increases.

7. The semiconductor device of claim 1, wherein the solder is applied to the inner wall of the trench.

8. The semiconductor device of claim 1, further comprising:
an external device connecting terminal provided on the second surface of the circuit board.

9. A circuit board comprising:
a first surface; and
a second surface on an opposite side of the circuit board as the first surface, wherein
a first electrode electrically connectable to a passive component is provided on the first surface of the circuit board,
a trench is formed through the first surface of the circuit board along at least a part of a peripheral edge of the first electrode, and
a plated layer is formed on an inner wall of the trench.

10. The circuit board of claim 9, wherein
a second electrode is provided on the first surface of the circuit board, and
the trench is formed between the first and second electrodes.

11. The circuit board of claim 9, wherein
an internal circuit is formed between the first surface of the circuit board and the second surface of the circuit board, and
a depth of the trench is less than a distance between the first surface of the circuit board and the internal circuit.

12. The circuit board of claim 11, wherein
an external circuit is formed on the first surface of the circuit board and on the second surface of the circuit board.

13. The circuit board of claim 9, wherein
the plated layer is formed of a metal material having low wettability to tin.

14. The circuit board of claim 13, wherein the metal material is nickel.

15. The circuit board of claim 9, wherein
the trench is formed such that a width of the trench becomes increasingly narrow as a depth of the trench increases.

16. A semiconductor device manufacturing method for a circuit board that includes a first surface through which a trench is formed and that includes a second surface on an opposite side of the circuit board as the first surface, wherein a plated layer is formed on an inner wall of the trench, the semiconductor device manufacturing method comprising:
bonding a passive component to a first electrode using solder, wherein the first electrode is electrically connectable to the passive component, the first electrode is provided on the first surface of the circuit board, and the trench is formed along at least a part of a peripheral edge of the first electrode;
electrically connecting the circuit board and a semiconductor chip; and
covering the first surface of the circuit board, surfaces of the semiconductor chip and the passive component, and an inside of the trench, with sealing resin.

17. The semiconductor device manufacturing method of claim 16, further comprising:
connecting an external device connecting terminal to the second surface of the circuit board using a conductive adhesive agent.

18. The semiconductor device manufacturing method of claim 16, further comprising:
forming the first electrode by applying a photolithography technique and an anisotropic etching technique to copper foil.

19. The semiconductor device manufacturing method of claim 18, further comprising:
forming a second electrode by applying the photolithography technique and the anisotropic etching technique to the copper foil, wherein the second electrode is electrically connectable to the passive component and provided on the first surface of the circuit board.

20. The semiconductor device manufacturing method of claim 19, wherein the trench is formed between the first and second electrodes.
